(19) United States
(12) Patent Application Publication
(10) Pub. No.: US 2007/0252615 A1
(43) Pub. Date: Nov. 1, 2007

(54) LOGIC-KEEPING APPARATUS FOR IMPROVING SYSTEM-LEVEL ELECTROSTATIC DISCHARGE ROBUSTNESS

(76) Inventors: Chyh-Yih Chang, Taipei County (TW); Ching-Hua Huang, Tainan County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, omitted

(21) Appl. No.: 11/309,104

(22) Filed: Jun. 23, 2006

(30) Foreign Application Priority Data
Apr. 26, 2006 (TW) 95114852

(51) Int. Cl. H03K 19/003

(52) U.S. Cl. 326/23

(57) ABSTRACT

A logic-keeping apparatus including a logic judgment unit and a noise-event detection unit is disclosed. When the level at the input terminal of the logic judgment unit is larger than a first level, the output terminal thereof outputs a first logic state; when the level at the input terminal is smaller than a second level, the output terminal thereof outputs a second logic state; when the level at the input terminal is between the first level and the second level, the output terminal thereof keeps the previous logic state. The noise-event detection unit is for detecting whether a noise-event occurs (for example, an ESD event). Wherein, when a noise-even occurs in the system, the noise-event detection unit keeps the level at the input terminal of the logic judgment unit between the first level and the second level.

### CROSS-REFERENCE TO RELATED APPLICATION

This application claims the priority benefit of Taiwan application serial no. 95114852, filed on Apr. 26, 2006. All disclosure of the Taiwan application is incorporated herein by reference.

### BACKGROUND OF THE INVENTION

1. Field of Invention

The present invention relates to a logic-keeping apparatus, and more particularly to a logic-keeping apparatus for improving system-level noise-event (for example, electrostatic discharge) robustness.

2. Description of the Related Art

An electronic product used in real surroundings usually suffers various noise-event impacts, for example, an electrostatic discharge (ESD) or an electromagnetic interfering (EMI). If there is no appropriate measure taken to provide protection, a noise-event is likely to damage the internal components of the electronic product. In particular, during an operation thereof, a noise-event probably causes the electronic product to a fatal failure, even burns down the internal components thereof. To avoid the above-mentioned accidents, a system is usually equipped with a protection circuit by design to deal with various noise-events; for example, by means of an ESD protection circuit, the electrostatic current is induced into a power-rail.

In U.S. Pat. No. 5,237,395, an ESD protection circuit for protecting power-rails is disclosed, while U.S. Pat. No. 5,237,395 provides another ESD protection circuit for protecting power-rails. All these conventional schemes are to manage to prolong the time for sustaining an ESD zapping by using a detection circuit, which is started up to protect chips during an ESD. On the other hand, U.S. Pat. No. 6,658,597 develops a system-level ESD protection circuit for preventing a system from damage caused by a sequence difference to turn on powers or by an ESD zapping. The above-mentioned prior arts are stated in the related patent specifications, thus they are omitted to describe for simplicity.

During a normal operation of a system, a noise-event is likely to affect the signal levels inside the system, which further leads to logic mistakes and consequently makes the system malfunction. Based on the above-mentioned situations, International Electrotechnical Commission (IEC) has already framed several protection and testing standards focusing on electromagnetic compatibility of a commercial electronic apparatus. In April 2001, for example, IEC published one of the protection and testing standards, titled as Electromagnetic Compatibility (EMC)—Part 4-2: Testing and Measurement Techniques—Electrostatic Discharge Immunity Test, or briefed as IEC.61000-4-2. According to the standard IEC.61000-4-2, the system logic states in an IC chip inside an electronic apparatus must keep unchanged when an ESD event occurs.

In the standard IEC.61000-4-2, the system-level testing environment is specified in detail, where a so-called system-level ‘A’ of ESD robustness means a system is required not be affected by an ESD and to keep all the existed data. To achieve the goal, the system experiencing an ESD is required not only to keep the circuit stability thereof, but also to assure the received data unchanged.

When an ESD event occurs, the system may receive incorrect data twisted by a transient system voltage or a transient grounding voltage. FIG. 1 is a signal graph of a received data immediately after an ESD event has occurred. The signal graph in the figure shows the system is suffered by a surge current with a peak amplitude during the beginning 0.7˜1 ns and with a followed significant amplitude during at least 60 ns. The aforementioned signal variation will certainly change the normal logic state of the data and result in a system failure. Therefore, a system must be assured that the received data will not be affected by an ESD event.

### SUMMARY OF THE INVENTION

An objective of the present invention is to provide a logic-keeping apparatus to prevent the received data from being affected by a noise-event (for example, ESD event), so as to keep the original state of the received data and the normal system operation and to improve the system-level electrostatic discharge robustness.

Based on the above-described objective, the present invention provides a logic-keeping apparatus, which includes a logic judgment unit and a noise-event detection unit. The logic judgment unit determines a logic state of the output terminal thereof according to the level of the input terminal thereof. Wherein, when the level of the input terminal thereof is larger than a first level, the output terminal thereof outputs a first logic state; when the level of the input terminal thereof is lower than a second level, the output terminal thereof outputs a second logic state; when the level of the input terminal thereof is between the first level and the second level, the level at the output terminal thereof is kept in the preceding logic state. The noise-event detection unit is coupled with the logic judgment unit. The noise-event detection unit is for detecting whether a noise-event occurs (for example, ESD). Wherein, when a noise-event occurs, the noise-event detection unit keeps the level at the input terminal of the logic judgment unit between the first level and the second level.

According to the logic-keeping apparatus provided by an embodiment of the present invention, the above-described logic judgment unit includes a Schmitt trigger circuit.

According to the logic-keeping apparatus provided by an embodiment of the present invention, the noise-event detection unit includes an ESD detector and a voltage driver. The ESD detector is for detecting whether an ESD occurs. The voltage driver is coupled with the ESD detector. When a detection result from the noise-event detection unit indicates that a noise-event occurs, the voltage driver outputs a driving voltage to the input terminal of the logic judgment unit; otherwise, no driving voltage is output. The level of the above-described driving voltage is between the first level and the second level.

The present invention employs a noise-event detection unit to detect a noise-event (an ESD, for example) and further to keep the level at the input terminal of the logic judgment unit between the first level and the second level and to keep the level at the output terminal of the logic judgment unit in the preceding logic state in response to a noise-event. Thus, the present invention is able to prevent the received data from being affected, so as to keep the system in normal operation and to improve the system-level robustness to confront a noise-event.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve for explaining the principles of the invention.

FIG. 1 is a signal graph of a received data immediately after an ESD event occurs.

FIG. 2 illustrates an embodiment of a logic-keeping apparatus for improving system-level electrostatic discharge robustness according to the present invention.

FIG. 3˜FIG. 10 illustrate embodiments of the logic-keeping apparatus in FIG. 2 according to the present invention.

### DESCRIPTION OF THE EMBODIMENTS

The so-called “noise-event” generally refers to an event possibly affecting the normal operation of a system, such as ESD or EMI. For the convenience and clearness of describing the spirit of the present invention and the technical features thereof, only ESD is used as an example to explain the operation process of a logic-keeping apparatus in response to a noise-event. In addition, an input buffer circuit of an integrated circuit (IC) is used as exemplary to describe an embodiment of the present invention hereinafter. The following embodiment and teachings do not limit the application scope of the present invention. Anyone skilled in the art is able to apply the present invention to any component for receiving data in a system to meet the need thereof.

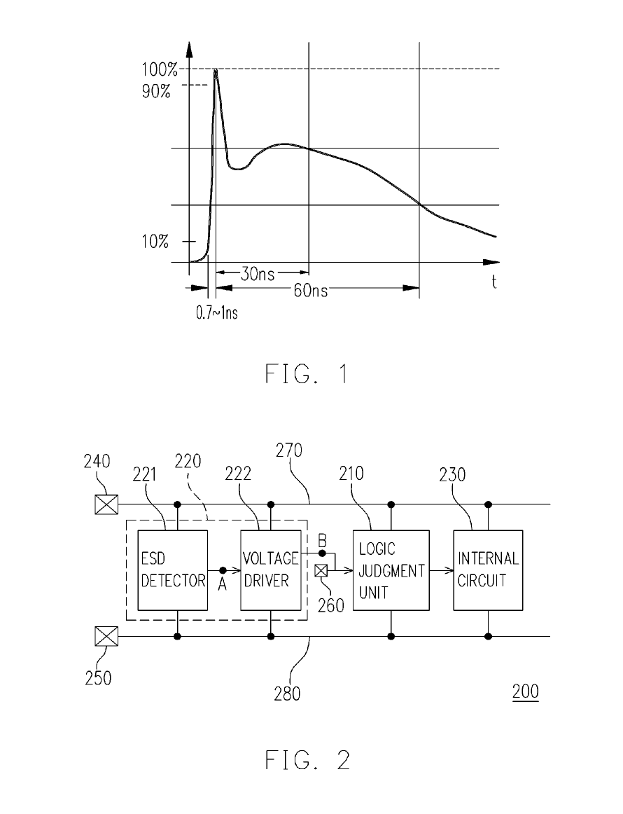

FIG. 2 illustrates an embodiment of a logic-keeping apparatus for improving system-level electrostatic discharge robustness according to the present invention. An IC 200 includes a logic-keeping apparatus, an internal circuit 230, a first power-rail 270, a second power-rail 280, a first bonding pad 240, a second bonding pad 250 and a third bonding pad 260. The above-mentioned logic-keeping apparatus includes a logic judgment unit 210 and a noise-event detection unit 220. In the embodiment, a system voltage supplied outside the IC 200 is provided to all devices inside the IC 200 via the bonding pad 240 and the first power-rail 270, while a grounding voltage supplied outside is provided to all devices inside the IC 200 via the bonding pad 250 and the second power-rail 280. The voltages delivered by the power-rails 270 and 280 are not limited to the above-mentioned designation; for example, the power-rail 270 can serve for delivering and providing the grounding voltage, while the power-rail 280 can serve for delivering and providing the system voltage. That is, the present invention can be applied to a power-rail pair with any voltage designation.

The logic-keeping apparatus herein serves as an input buffer of the IC 200. Under a normal operation condition, the logic-keeping apparatus receives external data of the IC 200 through the bonding pad 260 and buffers the received data, followed by delivering the received data to the internal circuit 230. When the system experiences an ESD impact, the signal of the bonding pad 260 may be in disorder and a wrong data is delivered to the internal circuit 230. If it is the case, the logic-keeping apparatus would filter out the wrong input signal and keeps the previously input logic state, which assures the wrong data during an ESD not to be received and further avoids the system from abnormal operations. Therefore, the logic-keeping apparatus is able to prevent the received data from being affected by a noise-event and maintain normal operations of the system. Even after the EDS impact, the system is exempted from a system reset, which is supposedly to be conducted if the system is affected or damaged. Therefore, a system equipped with the logic-keeping apparatus provided by the present invention meets the requirement of system-level ‘A’ of ESD robustness specified in the standard IEC.61000-4-2.

In the logic-keeping apparatus, the logic judgment unit 210 determines the logic state of the output terminal thereof according to the level of the input terminal thereof. When the level at the input terminal of the logic judgment unit 210 is larger than a first level, the output terminal thereof outputs a first logic state; when the level at the input terminal thereof is smaller than a second level, the output terminal thereof outputs a second logic state; when the level at the input terminal thereof is between the first level and the second level (as called a “hysteresis zone”), the output terminal thereof keeps the previous logic state. In the embodiment, the logic judgment unit 210 includes a Schmitt trigger circuit. The noise-event detection unit 220 is coupled with the logic judgment unit 210 for detecting whether a noise-event occurs. When the system experiences an ESD impact, the ESD would affect the system voltage, the grounding voltage and the input signal which are delivered through the bonding pads 240, 250, 260, respectively. Therefore, the noise-event detection unit 220 is for detecting the level variation of the power-rails 270 and 280. When a noise-event occurs, the noise-event detection unit 220 keeps the level at the input terminal of the logic judgment unit 210 in the hysteresis zone.

In the embodiment, the above-described noise-event detection unit 220 includes an ESD detector 221 and a voltage driver 222. The ESD detector 221 is for detecting whether a noise-event occurs. The voltage driver 222 is coupled with the ESD detector 221. When the detection result of the ESD detector 221 (i.e. the signal of the node A in FIG. 2) indicates an ESD occurs, the voltage driver 222 outputs a driving voltage to the input terminal of the logic judgment unit 210, wherein the level of the driving voltage falls in the hysteresis zone of the logic judgment unit 210 by set; otherwise, no driving voltage is output. The so-called “no driving voltage is output” in the embodiment can mean the output terminal of the voltage driver 222 (the node B in FIG. 2) takes floating state or high impedance state by set.

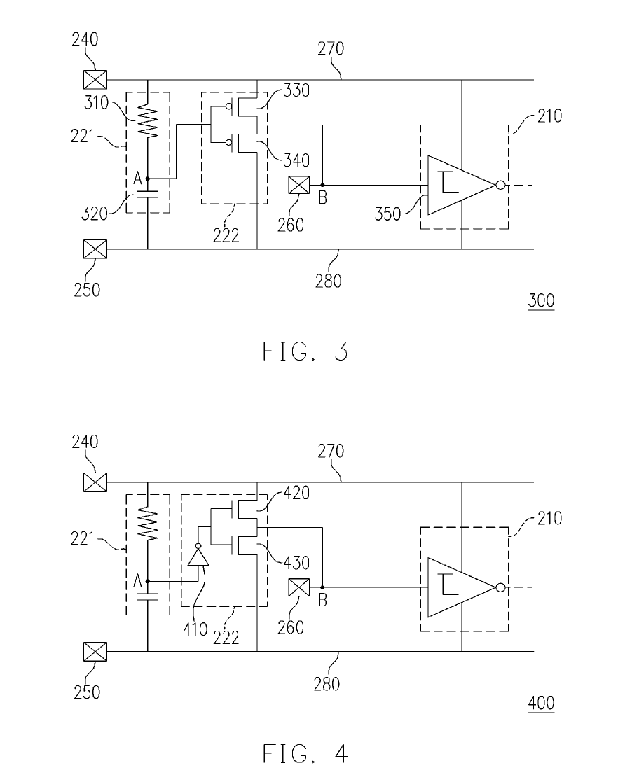

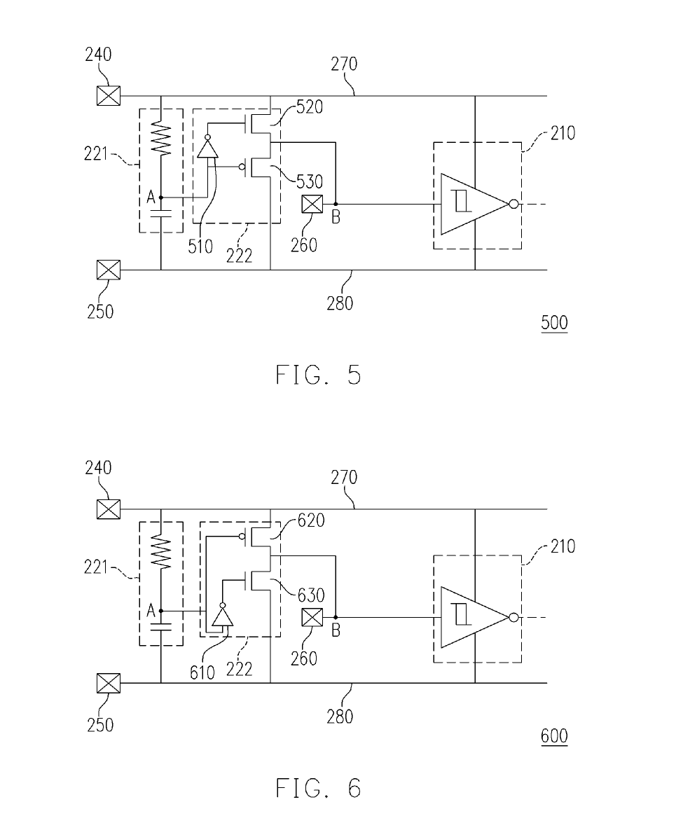

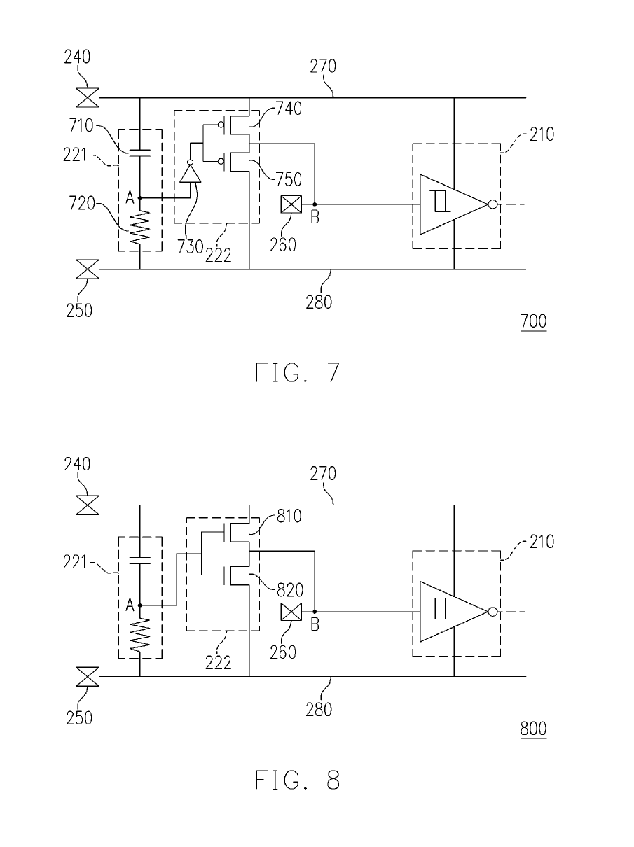

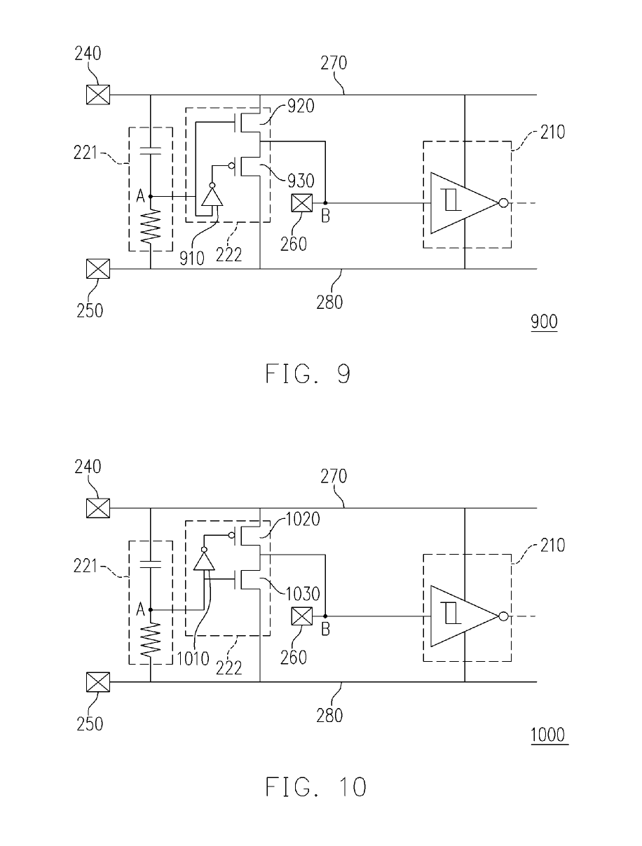

FIG. 3 illustrates an embodiment of the above-described logic-keeping apparatus according to the present invention. Referring to FIG. 3, in the logic-keeping apparatus 300, the ESD detector 221 includes a resistor 310 and a capacitor 320. The resistor 310 and the capacitor 320 are connected in series between the first power-rail 270 and the second power-rail 280. Wherein, at the common connection point between the resistor 310 and the capacitor 320, i.e. at the node A, the detection result of the ESD detector 221 is output. The voltage driver 222 includes a first impedance switch 330 and a second impedance switch 340, which can be implemented by P-type transistors. The impedance switches 330 and 340 respectively determine the ON/OFF state between the first connection terminal and the second connection terminal thereof according to the control terminal thereof. Wherein, the ON state between the first connection terminal and the second connection terminal of the impedance switch 330 corresponds to a first impedance the impedance switch 330 possesses, while the ON state between the first connection terminal and the second connection terminal of the impedance switch 340 corresponds to a second impedance the impedance switch 340 possesses. The impedance switches 330 and 340 are connected in series between the first power-rail 270 and the second power-rail 280. The control terminals of the impedance switches 330 and 340 are connected to the ESD detector 221. In the present embodiment, the logic judgment unit 210 includes an NOT-gate with a Schmitt trigger circuit 350.

Under a normal operation condition of the system, the capacitor 320 in the ESD detector 221 is fully charged, which keeps the node A at a high level (corresponding to the level of the power-rail 270). Thus, the impedance switches 330 and 340 take OFF state since the node A keeps the high level. At the point, the output terminal of the voltage driver 222 takes floating state and outputs no driving voltage to the logic judgment unit 210. The logic judgment unit 210 of the logic-keeping apparatus 300 receives and buffers the external data of the IC via the bonding pad 260, followed by delivering the external data to a next stage circuit (for example, the internal circuit 230 in FIG. 2).

When the system experiences an ESD impact, the ESD would affect the system voltage, the grounding voltage and the input signal delivered through the bonding pads 240, 250 and 260. The resistor 310 and the capacitor 320 connected in series to each other in the ESD detector 221 possess an RC time constant. If the voltage levels of the power-rails 270 and 280 get oscillated as an ESD occurs, the transient response behaviors of the resistor 310 and the capacitor 320 make the level at the node A far lower than the level of the power-rail 270, which turns on the impedance switches 330 and 340. Since the impedance switches 330 and 340 in ‘on state’ respectively possess a first impedance and a second impedance, therefore, the driving voltage output from the voltage driver 222 can be adjusted to fall in the hysteresis zone by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the NOT-gate 350 is able to hold the previous output logic state. Thus, any incorrect data during an ESD occurs would not be received, which further avoids the system from conducting abnormal operations. In short, the logic-keeping apparatus 300 is able to prevent the received data from being affected by a noise-event and to maintain the system in normal operations.

FIG. 4˜FIG. 6 illustrate other embodiments of the logic-keeping apparatus in FIG. 2 according to the present invention. The logic-keeping apparatuses 400, 500 and 600 in FIG. 4˜FIG. 6 are similar to the logic-keeping apparatus 300 in FIG. 3, except for the implementation of the voltage driver 222. For simplicity, the same portion as in FIG. 3 is omitted to describe.

Referring to FIG. 4, the voltage driver 222 includes an NOT-gate 410, a first impedance switch 420 and a second impedance switch 430. The input terminal of the NOT-gate 410 is coupled with the ESD detector 221. The impedance switches 420 and 430 herein can be implemented by an N-type transistor, respectively. The impedance switches 420 and 430 respectively decide the ON/OFF state between the first connection terminal and the second connection terminal thereof according to the control terminal thereof. Wherein, the impedance switch 420 possesses the first impedance in response to the ON state between the first connection terminal and the second connection terminal thereof, while the impedance switch 430 possesses the second impedance in response to the ON state between the first connection terminal and the second connection terminal thereof. The impedance switches 420 and 430 are connected in series between the first power-rail 270 and the second power-rail 280. The control terminals of the impedance switches 420 and 430 are connected to the output terminal of the NOT-gate 410.

Under a normal operation condition, the ESD detector 221 keeps the node A in a high level (corresponding to the level of the power-rail 270). At the point, the NOT-gate 410 converts the high level of the node A into a low level, which is further output to the control terminals of the impedance switches 420 and 430. Thus, the impedance switches 420 and 430 take OFF state due to the high level the node A holds. The output terminal of the voltage driver 222 takes floating state, which does not allow outputting a driving voltage to the logic judgment unit 210. The logic judgment unit 210 of the logic-keeping apparatus 400 is able to receive and buffer an external data of the IC via the bonding pad 260, followed by delivering the received external data to the next circuit (for example, the internal circuit 230 in FIG. 2).

When the system experiences an ESD impact, the voltage levels of the power-rails 270 and 280 oscillate, which makes the level of the node A far lower than the level of the power-rail 270 (in terms of the NOT-gate 410, the level of the node A at the point is considered as a logic low level). The NOT-gate 410 converts the logic low level of the node A into a logic high level, followed by outputting the logic high level to the control terminals of the impedance switches 420 and 430 to turn on the switches 420 and 430. Since the impedance switches 420 and 430 in ON state possess the first impedance and the second impedance, respectively, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 400 is able to prevent the received data from being affected by a noise-event and to maintain the system in normal operations.

Referring to FIG. 5, the voltage driver 222 includes an NOT-gate 510, a first impedance switch 520 and a second impedance switch 530. The input terminal of the NOT-gate 510 is coupled with the ESD detector 221. The impedance switch 520 herein can be implemented by an N-type transistor and the impedance switch 530 herein can be implemented by a P-type transistor. The impedance switches 520 and 530 respectively decide the ON/OFF state between the first connection terminal and the second connection terminal thereof according to the control terminal thereof. Wherein, the impedance switch 520 possesses the first impedance in response to the ON state between the first connection terminal and the second connection terminal thereof, while the impedance switch 530 possesses the second impedance in response to the ON state between the first connection terminal and the second connection terminal thereof. The impedance switches 520 and 530 are connected in series between the first power-rail 270 and the second power-rail 280. The control terminal of the impedance switch 520 is connected to the output terminal of the NOT-gate 510, while the control terminal of the impedance switch 530 is connected to the ESD detector 221.

Under a normal operation condition, the ESD detector 221 keeps the node A in a high level (corresponding to the level of the power-rail 270). At the point, the NOT-gate 410 converts the high level of the node A into a low level, which is further output to the control terminal of the impedance switch 520. Thus, the impedance switches 520 and 530 take OFF state due to the high level the node A holds. The output terminal of the voltage driver 222 takes floating state, which does not allow outputting a driving voltage to the logic judgment unit 210. The logic judgment unit 210 of the logic-keeping apparatus 500 is able to receive and buffer an external data of the IC via the bonding pad 260, followed by delivering the received external data to the next circuit (for example, the internal circuit 230 in FIG. 2).

When the system experiences an ESD impact, the voltage levels of the power-rails 270 and 280 oscillate, which makes the level of the node A far lower than the level of the power-rail 270 (in terms of the NOT-gate 510, the level of the node A at the point is considered as a logic low level). The NOT-gate 510 converts the logic low level of the node A into a logic high level, followed by outputting the logic high level to the control terminals of the impedance switch 520 to turn on the switches 520 and 530. Since the impedance switches 520 and 530 in ON state possess the first impedance and the second impedance, respectively, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 500 is able to prevent the received data from being affected by a noise-event and to maintain the system in normal operations.

Referring to FIG. 6, the voltage driver 222 includes an NOT-gate 610, a first impedance switch 620 and a second impedance switch 630. The input terminal of the NOT-gate 610 is coupled with the ESD detector 221. The impedance switch 620 herein can be implemented by a P-type transistor and the impedance switch 630 herein can be implemented by an N-type transistor. The impedance switches 620 and 630 respectively decide the ON/OFF state between the first connection terminal and the second connection terminal thereof according to the control terminal thereof. Wherein, the impedance switch 620 possesses the first impedance in response to the ON state between the first connection terminal and the second connection terminal thereof, while the impedance switch 630 possesses the second impedance in response to the ON state between the first connection terminal and the second connection terminal thereof. The impedance switches 620 and 630 are connected in series between the first power-rail 270 and the second power-rail 280. The control terminal of the impedance switch 620 is connected to the ESD detector 221, while the control terminal of the impedance switch 630 is connected to the output terminal of the NOT-gate 610.

Under a normal operation condition, the ESD detector 221 keeps the node A in a high level (corresponding to the level of the power-rail 270). At the point, the NOT-gate 610 converts the high level of the node A into a low level, which is further output to the control terminal of the impedance switch 630. Thus, the impedance switches 620 and 630 take OFF state due to the high level the node A holds. The output terminal of the voltage driver 222 takes floating state, which does not allow outputting a driving voltage to the logic judgment unit 210. The logic judgment unit 210 of the logic-keeping apparatus 600 is able to receive and buffer an external data of the IC via the bonding pad 260, followed by delivering the received external data to the next circuit (for example, the internal circuit 230 in FIG. 2).

When the system experiences an ESD impact, the level of the node A is far lower than the level of the power-rail 270 (in terms of the NOT-gate 610, the level of the node A at the point is considered as a logic low level). The NOT-gate 610 converts the logic low level of the node A into a logic high level, followed by outputting the logic high level to the control terminals of the impedance switch 620 to turn on the switches 620 and 630. Since the impedance switches 620 and 630 in ON state possess the first impedance and the second impedance, respectively, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 600 is able to prevent the received data from being affected by a noise-event and to maintain the system in normal operations.

FIG. 7˜FIG. 10 illustrate other embodiments of the logic-keeping apparatus in FIG. 2 according to the present invention. The logic-keeping apparatus 700 in FIG. 7 is similar to the logic-keeping apparatus 300 in FIG. 3, except for the implementation of the ESD detector 221 and the voltage driver 222. For simplicity, the same portion as in FIG. 3 is omitted to describe. Referring to FIG. 7, the ESD detector 221 includes a capacitor 710 and a resistor 720. The resistor 720 is connected to the second power-rail 280, while the capacitor 710 is connected between the first power-rail 270 and the resistor 720. Wherein, the common connection point between the resistor 720 and the capacitor 710 (i.e. the node A) outputs the detection result of the ESD detector 221. The voltage driver 222 includes an NOT-gate 730, a first impedance switch 740 and a second impedance switch 750. The input terminal of the NOT-gate 730 is coupled with the ESD detector 221. The impedance switches 740 and 750 herein can be implemented by a P-type transistor, respectively. The impedance switches 740 and 750 respectively decide the ON/OFF state between the first connection terminal and the second connection terminal thereof according to the control terminal thereof. Wherein, the impedance switch 740 possesses the first impedance in response to the ON state between the first connection terminal and the second connection terminal thereof, while the impedance switch 750 possesses the second impedance in response to the ON state between the first connection terminal and the second connection terminal thereof. The impedance switches 740 and 750 are connected in series between the first power-rail 270 and the second power-rail 280. The control terminals of the impedance switches 740 and 750 are connected to the output terminal of the NOT-gate 730.

Under a normal operation condition, the capacitor 710 in the ESD detector 221 keeps the node A in a low level since the capacitor 710 is fully charged (corresponding to the level of the power-rail 280). At the point, the NOT-gate 730 converts the low level of the node A into a high level, which is further output to the control terminals of the impedance switches 740 and 750. Thus, the impedance switches 740 and 750 take OFF state due to the low level the node A holds. The output terminal of the voltage driver 222 takes floating state, which does not allow outputting a driving voltage to the logic judgment unit 210. The logic judgment unit 210 of the logic-keeping apparatus 700 is able to receive and buffer an external data of the IC via the bonding pad 260, followed by delivering the received external data to the next circuit (for example, the internal circuit 230 in FIG. 2).

When the system experiences an ESD impact, the ESD would affect the system voltage, the grounding voltage and the input signal which are delivered through the bonding pads 240, 250, 260, respectively. The resistor 720 and the capacitor 710 connected in series to each other in the ESD detector 221 possess an RC time constant. If the voltage levels of the power-rails 270 and 280 get oscillated as an ESD occurs, the transient response behaviors of the resistor 720 and the capacitor 710 make the level at the node A far higher than the level of the power-rail 280 (in terms of the NOT-gate 730, the level of the node A is considered as a logic high level). The NOT-gate 730 converts the logic high level of the node A into a logic low state, followed by outputting the logic low state to the control terminals of the impedance switches 740 and 750, which turns on the impedance switches 740 and 750. Since the impedance switches 740 and 750 in ‘on state’ respectively possess a first impedance and a second impedance, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 700 is able to prevent the received data from being affected by a noise-event and to maintain the system in normal operations.

The logic-keeping apparatuses 800, 900 and 1000 in FIG. 8˜FIG. 10 are similar to the logic-keeping apparatus 700 in FIG. 7, except for the implementation of the voltage driver 222. For simplicity, the same portion as in FIG. 3 is omitted to describe.

Referring to FIG. 8, the voltage driver 222 in the logic-keeping apparatus 700 includes a first impedance switch 810 and a second impedance switch 820. The impedance switches 810 and 820 herein can be implemented by an N-type transistor, respectively. The impedance switches 810 and 820 respectively decide the ON/OFF state between the first connection terminal and the second connection terminal thereof according to the control terminal thereof. Wherein, the impedance switch 810 possesses the first impedance in response to the ON state between the first connection terminal and the second connection terminal thereof, while the impedance switch 820 possesses the second impedance in response to the ON state between the first connection terminal and the second connection terminal thereof. The impedance switches 810 and 820 are connected in series between the first power-rail 270 and the second power-rail 280. The control terminals of the impedance switches 810 and 820 are connected to the ESD detector 221.

Under a normal operation condition, the ESD detector 221 keeps the node A in a low level (corresponding to the level of the power-rail 280). At the point, the impedance switches 810 and 820 take OFF state due to the low level the node A holds. The output terminal of the voltage driver 222 takes floating state, which does not allow outputting a driving voltage to the logic judgment unit 210. The logic judgment unit 210 of the logic-keeping apparatus 800 is able to receive and buffer an external data of the IC via the bonding pad 260, followed by delivering the received external data to the next circuit (for example, the internal circuit 230 in FIG. 2).

When the system experiences an ESD impact, the ESD makes the level of the node A far higher than the level of the power-rail 280. Thus, the impedance switches 810 and 820 are turned on. Since the impedance switches 810 and 820 in ON state possess the first impedance and the second impedance, respectively, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 800 is able to prevent the received data from being affected by a noise-event and to maintain the system in normal operations.

Referring to FIG. 9, the voltage driver 222 in the logic-keeping apparatus 900 includes an NOT-gate 910, a first impedance switch 920 and a second impedance switch 930. The input terminal of the NOT-gate 910 is coupled with the ESD detector 221. The impedance switches 920 and 930 herein can be implemented by an N-type transistor and a P-type transistor, respectively. The impedance switches 920 and 930 respectively decide the ON/OFF state between the first connection terminal and the second connection terminal thereof according to the control terminal thereof. Wherein, the impedance switch 920 possesses the first impedance in response to the ON state between the first connection terminal and the second connection terminal thereof, while the impedance switch 930 possesses the second impedance in response to the ON state between the first connection terminal and the second connection terminal thereof. The impedance switches 920 and 930 are connected in series between the first power-rail 270 and the second power-rail 280. The control terminal of the impedance switch 920 is connected to the ESD detector 221, while the control terminal of the impedance switch 930 is connected to the output terminal of the NOT-gate 910.

Under a normal operation condition, the ESD detector 221 keeps the node A in a low level (corresponding to the level of the power-rail 280). At the point, the NOT-gate converts the low level of the node A into a high level, which is then output to the control terminal of the impedance switch 930. Thus, the impedance switches 920 and 930 take OFF state due to the low level the node A holds. The output terminal of the voltage driver 222 takes floating state, which does not allow outputting a driving voltage to the logic judgment unit 210. The logic judgment unit 210 of the logic-keeping apparatus 900 is able to receive and buffer an external data of the IC via the bonding pad 260, followed by delivering the received external data to the next circuit (for example, the internal circuit 230 in FIG. 2).

When the system experiences an ESD impact, the ESD detector 221 makes the level of the node A far higher than the level of the power-rail 280 (in terms of the NOT-gate 910, the level of the node A is considered as a logic high level). At the point, the NOT-gate 910 converts the high level of the node A into a low level, followed by outputting the low level to the control terminal of the impedance switch 930. Thus, the impedance switches 920 and 930 are turned on. Since the impedance switches 920 and 930 in ON state possess the first impedance and the second impedance, respectively, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 900 is able to prevent the received data from being affected by a noise-event and to maintain the system in normal operations.

Referring to FIG. 10, the voltage driver 222 in the logic-keeping apparatus 1000 includes an NOT-gate 1010, a first impedance switch 1020 and a second impedance switch 1030. The input terminal of the NOT-gate 1010 is coupled with the ESD detector 221. The impedance switches 1020 and 1030 herein can be implemented by a P-type transistor and an N-type transistor, respectively. The impedance switches 1020 and 1030 respectively decide the ON/OFF state between the first connection terminal and the second connection terminal thereof according to the control terminal thereof. Wherein, the impedance switch 1020 possesses the first impedance in response to the ON state between the first connection terminal and the second connection terminal thereof, while the impedance switch 1030 possesses the second impedance in response to the ON state between the first connection terminal and the second connection terminal thereof. The impedance switches 1020 and 1030 are connected in series between the first power-rail 270 and the second power-rail 280. The control terminal of the impedance switch 1020 is connected to the output terminal of the NOT-gate 1010, while the control terminal of the impedance switch 1030 is connected to the ESD detector 221.

Under a normal operation condition, the ESD detector 221 keeps the node A in a low level (corresponding to the level of the power-rail 280). At the point, the NOT-gate 1010 converts the low level of the node A into a high level and outputs the converted high level to the control terminal of the impedance switch 1020. Thus, the impedance switches 1020 and 1030 take OFF state due to the low level the node A holds. The output terminal of the voltage driver 222 takes floating state, which does not allow outputting a driving voltage to the logic judgment unit 210. The logic judgment unit 210 of the logic-keeping apparatus 1000 is able to receive and buffer an external data of the IC via the bonding pad 260, followed by delivering the received external data to the next circuit (for example, the internal circuit 230 in FIG. 2).

When the system experiences an ESD impact, the ESD makes the level of the node A far higher than the level of the power-rail 280. Thus, the impedance switches 1020 and 1030 are turned on. Since the impedance switches 1020 and 1030 in ON state possess the first impedance and the second impedance, respectively, therefore, the driving voltage output from the voltage driver 222 can be adjusted to fall in the hysteresis zone of the logic judgment unit 210 by setting an impedance proportion between the first impedance and the second impedance. The driving voltage output from the voltage driver 222 enables the level at the input terminal of the logic judgment unit 210 (the voltage of the node B) to keep in the hysteresis zone. Thus, when the system experiences an ESD impact and the signal delivered through the bonding pad 260 is in disorder, since the voltage driver 222 keeps the level at the input terminal of the logic judgment unit 210 (i.e. the voltage of the node B) in the hysteresis zone at the point, the logic judgment unit 210 is able to hold the previous output logic state. Thus, any incorrect data during an ESD occurs would not be received, which further avoids the system from conducting abnormal operations. In short, the logic-keeping apparatus 1000 is able to prevent the received data from being affected by a noise-event and to maintain the system in normal operations.

In summary, the present invention uses a noise-event detection unit to detect a noise-event (for example, an ESD event) and further to keep the level at the input terminal of the logic judgment unit between the first level and the second level during a noise-event occurrence, so that the output terminal of the logic judgment unit keeps the previous logic state. Therefore, the present invention is able to prevent the received data from being affected by the noise-event, maintain the system in normal operations and improve the system-level electrostatic discharge robustness.

It will be apparent to those skilled in the art that various modifications and variations can be made to the structure of the present invention without departing from the scope or spirit of the invention. In view of the foregoing, it is intended that the specification and examples to be considered as exemplary only, with a true scope and spirit of the invention being indicated by the following claims and their equivalents.

1. A logic-keeping apparatus, comprising:
a logic judgment unit, used for determining a logic state of the output terminal thereof according to a level of an input terminal thereof, wherein when the level of the input terminal is larger than a first level, the output terminal thereof outputs a first logic state; when the level of the input terminal is smaller than a second level, the output terminal thereof outputs a second logic state; when the level of the input terminal is between the first level and the second level, the output terminal thereof keeps a previous logic state; and
a noise-event detection unit, coupled with the logic judgment unit for detecting whether a noise-event occurs, wherein when a noise-event occurs, the noise-event detection unit keeps the level of the input terminal of the logic judgment unit between the first level and the second level.

2. The logic-keeping apparatus as recited in claim 1, wherein the noise-event comprises electrostatic discharge (ESD).

3. The logic-keeping apparatus as recited in claim 1, wherein the logic judgment unit comprises a Schmitt trigger circuit.

4. The logic-keeping apparatus as recited in claim 1, wherein the noise-event detection unit comprises:
an ESD detector, used for detecting whether ESD occurs; and
a voltage driver, coupled with the ESD detector for outputting a driving voltage to the input terminal of the logic judgment unit when the detection result of the ESD detector indicates that ESD occurs; otherwise, not outputting the driving voltage, wherein
the level of the driving voltage is between the first level and the second level.

5. The logic-keeping apparatus as recited in claim 4, wherein the ESD detector comprises:
a resistor, wherein the first terminal thereof is coupled with a first power-rail, while the second terminal of the resistor outputs the detection result of the ESD detector; and
a capacitor, wherein the first terminal thereof is coupled with the second terminal of the resistor, while the second terminal of the capacitor is coupled with a second power-rail.

6. The logic-keeping apparatus as recited in claim 5, wherein the first power-rail is used for supplying a system voltage, while the second power-rail is used for supplying a grounding voltage.

7. The logic-keeping apparatus as recited in claim 5, wherein the first power-rail is used for supplying a grounding voltage, while the second power-rail is used for supplying a system voltage.

8. The logic-keeping apparatus as recited in claim 4, wherein the voltage driver comprises:
a first impedance switch, used for deciding ON/OFF state between a first connection terminal and a second connection terminal thereof according to a control terminal thereof, wherein the first impedance switch possesses a first impedance in response to ON state between the first connection terminal and the second connection terminal thereof; and the first connection terminal, the second connection terminal and the control terminal of the first impedance switch are coupled with a first power-rail, the input terminal of the logic judgment unit and the ESD detector, respectively; and
a second impedance switch, used for deciding ON/OFF state between a first connection terminal and a second connection terminal thereof according to a control terminal thereof, wherein the second impedance switch possesses a second impedance in response to ON state between the first connection terminal and the second connection terminal thereof; and the first connection terminal, the second connection terminal and the control terminal of the second impedance switch are coupled with the second connection terminal of the first impedance switch, a second power-rail and the ESD detector, respectively.

9. The logic-keeping apparatus as recited in claim 8, wherein both the first impedance switch and the second impedance switch respectively include a P-type transistor.

10. The logic-keeping apparatus as recited in claim 8, wherein both the first impedance switch and the second impedance switch respectively include an N-type transistor.

11. The logic-keeping apparatus as recited in claim 4, wherein the voltage driver comprises:
an NOT-gate, wherein a input terminal thereof is coupled with the ESD detector;
a first impedance switch, used for deciding ON/OFF state between a first connection terminal and a second connection terminal thereof according to a control terminal thereof, wherein the first impedance switch possesses a first impedance in response to ON state between the first connection terminal and the second connection terminal thereof; and the first connection terminal, the second connection terminal and the control terminal of the first impedance switch are coupled with a first power-rail, the input terminal of the logic judgment unit and an output terminal of the NOT-gate, respectively; and
a second impedance switch, used for deciding ON/OFF state between a first connection terminal and a second connection terminal thereof according to a control terminal thereof, wherein the second impedance switch possesses a second impedance in response to ON state between the first connection terminal and the second connection terminal thereof; and the first connection terminal, the second connection terminal and the control terminal of the second impedance switch are coupled with the second connection terminal of the first impedance switch, a second power-rail and the output terminal of the NOT-gate, respectively.

12. The logic-keeping apparatus as recited in claim 11, wherein both the first impedance switch and the second impedance switch respectively include a P-type transistor.

13. The logic-keeping apparatus as recited in claim 11, wherein both the first impedance switch and the second impedance switch respectively include an N-type transistor.

14. The logic-keeping apparatus as recited in claim 4, wherein the voltage driver comprises:
an NOT-gate, wherein an input terminal thereof is coupled with the ESD detector;
a first impedance switch, used for deciding ON/OFF state between a first connection terminal and a second connection terminal thereof according to a control terminal thereof, wherein the first impedance switch possesses a first impedance in response to ON state between the first connection terminal and the second connection terminal thereof; and the first connection terminal, the second connection terminal and the control terminal of the first impedance switch are coupled with a first power-rail, the input terminal of the logic judgment unit and an output terminal of the NOT-gate, respectively; and
a second impedance switch, used for deciding ON/OFF state between a first connection terminal and a second connection terminal thereof according to a control terminal thereof, wherein the second impedance switch possesses a second impedance in response to ON state between the first connection terminal and the second connection terminal thereof; and the first connection terminal, the second connection terminal and the control terminal of the second impedance switch are coupled with the second connection terminal of the first impedance switch, a second power-rail and the ESD detector, respectively.

15. The logic-keeping apparatus as recited in claim 14, wherein the first impedance switch includes an N-type transistor, while the second impedance switch includes a P-type transistor.

16. The logic-keeping apparatus as recited in claim 14, wherein the first impedance switch includes a P-type transistor, while the second impedance switch includes an N-type transistor.

17. The logic-keeping apparatus as recited in claim 4, wherein the voltage driver comprises:
an NOT-gate, wherein an input terminal thereof is coupled with the ESD detector;
a first impedance switch, used for deciding ON/OFF state between a first connection terminal and a second connection terminal thereof according to a control terminal thereof, wherein the first impedance switch possesses a first impedance in response to ON state between the first connection terminal and the second connection terminal thereof; and the first connection terminal, the second connection terminal and the control terminal of the first impedance switch are coupled with a first power-rail, the input terminal of the logic judgment unit and the ESD detector, respectively; and
a second impedance switch, used for deciding ON/OFF state between a first connection terminal and a second connection terminal thereof according to a control terminal thereof, wherein the second impedance switch possesses a second impedance in response to ON state between the first connection terminal and the second connection terminal thereof; and the first connection terminal, the second connection terminal and the control terminal of the second impedance switch are coupled with the second connection terminal of the first impedance switch, a second power-rail and an output terminal of the NOT-gate, respectively.

18. The logic-keeping apparatus as recited in claim 17, wherein the first impedance switch includes an N-type transistor, while the second impedance switch includes a P-type transistor.

19. The logic-keeping apparatus as recited in claim 17, wherein the first impedance switch includes a P-type transistor, while the second impedance switch includes an N-type transistor.
